(19) United States
(12) Patent Application Publication
(10) Pub. No.: US 2010/0071942 A1
(43) Pub. Date: Mar. 25, 2010

(54) CIRCUIT BOARD WITH LOW NOISE

(75) Inventor: MING-FENG LEE, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/327,950

(22) Filed: Dec. 4, 2008

(30) Foreign Application Priority Data
Sep. 25, 2008 (CN) 200810304680.0

(51) Int. Cl. H05K 1/18

(52) U.S. Cl. 174/260

(57) ABSTRACT

A circuit board includes an analog area and a digital area. The analog area includes an analog ground layer and an analog wiring layer formed on the analog ground layer. The digital area includes a digital ground layer and a digital wiring layer formed on the digital ground layer. The digital ground layer is connected with the analog ground layer to form a main ground layer. The digital wiring layer is separate from the analog wiring layer.

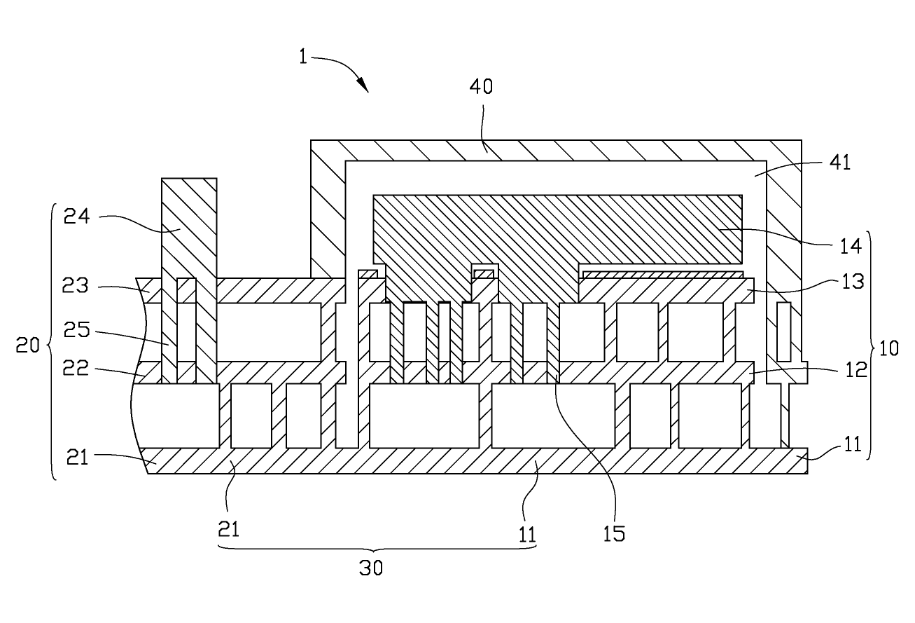

### BACKGROUND

1. Technical Field

The present disclosure relates to circuit boards and, particularly, to a circuit board with low noise.

2. Description of Related Art

A typical circuit board includes a loading layer, a wiring layer, and a ground layer. An electronic component may be placed on the loading layer of the circuit board. Signal pins and ground pins of the electronic component are electrically connected to the wiring layer and the ground layer of the typical circuit board. The electronic component may be analog or digital electronic components based on their signal characteristics. The analog electronic component includes audio chips, amplifiers, and power supplies. The digital electronic components include digital signal processors (DSP), microprocessors, and image signal drivers. The problems associated with placing analog and digital circuitry corresponding to the analog and digital electronic components onto the same circuit board include high radio frequency noise produced by digital circuits, which typically interferes with sensitive, noise-susceptible analog circuitry.

The typical circuit board usually includes separate analog and digital areas to solve the above problem. Each area includes an individual loading layer, wiring layer, and ground layer. If the analog area is separated from the digital area, noise in the digital area should not affect the analog area, and the analog circuitry should have better performance. However, it is difficult to layout line traces of the circuit board. For smaller sized products, the ground layer of the analog area may be too small and work like a floating trace. If any noise gets to the ground layer of the analog area, analog signal performance will be affected.

What is needed, therefore, is a circuit board to overcome the above-described problem.

### BRIEF DESCRIPTION OF THE DRAWINGS

Many aspects of the present disclosure can be better understood with references to the accompanying drawing. The components in the drawing are not necessarily drawn to scale, the emphasis instead being placed upon clearly illustrating the principles of the present circuit board.

The drawing is a schematic, cross-sectional view of a circuit board according to an exemplary embodiment.

### DETAILED DESCRIPTION OF THE EMBODIMENTS

Embodiments of the present disclosure will now be described in detail below, with references to the accompanying drawing.

Referring to the drawing, an embodiment of a circuit board 1 of an electronic device (not shown) is shown. The circuit board 1 may be a printed circuit board, and includes an analog area 10, a digital area 20, and a shielding case 40.

The analog area 10 includes an analog ground layer 11, an analog wiring layer 12, an analog loading layer 13, and an analog component 14.

The analog wiring layer 12 and the analog loading layer 13 are stacked on the analog ground layer 11 in sequence. The analog ground layer 11 absorbs noise signals produced therein. The analog loading layer 13 may be an insulating layer capable of protecting the analog wiring layer 12.

The analog component 14 is mounted on a surface of the analog loading layer 13 away from the analog wiring layer 12. The analog component 14 may be an audio chip, an amplifier, a power supplier, a microphone, and so on. The analog component 14 has a number of signal pins 15 electrically connected to the analog wiring layer 12. In one embodiment, the analog component 14 also has at least one ground pin (not shown) connected to the analog ground layer 11.

The digital area 20 includes a digital ground layer 21, a digital wiring layer 22, a digital loading layer 23, and a digital component 24.

The digital wiring layer 22 and the digital loading layer 23 are stacked on the digital ground layer 21 in sequence. The digital ground layer 21 absorbs noise signals therein. The digital loading layer 23 may be an insulating layer protecting the digital wiring layer 22. The digital ground layer 21, the digital wiring layer 22, and the digital loading layer 23 are substantially coplanar with the analog ground layer 11, the analog wiring layer 12, and the analog loading layer 13, respectively. The digital wiring layer 22 is separated from the analog wiring layer 12 to prevent noise in the digital wiring layer 22 from interfering with the analog wiring layer 12. In the illustrated embodiment, the digital loading layer 23 is also separated from the analog loading layer 13. The digital ground layer 21 is connected with the analog ground layer 11 to form a larger main ground layer 30. The digital wiring layer 22 and the analog wiring layer 12 are formed at a same side of the main ground layer 30.

The digital component 24 is mounted on a surface of the digital loading layer 23 away from the digital wiring layer 22. The digital component 24 may be a digital signal processor (DSP), a microprocessor, an image signal (video) driver, and so on. The digital component 24 has a number of signal pins 25 electrically connected to the digital wiring layer 22. In one embodiment, the digital component 24 also has at least one ground pin (not shown) connected to the digital ground layer 21.

The shielding case 40 is mounted on the digital loading layer 23 or analog loading layer 13 and defines a receiving space 41 and receives the analog component 14 therein. In the illustrated embodiment, the analog loading layer 13 is surrounded by the digital loading layer 23, and the shielding case 40 is mounted on the digital loading layer 23 surrounding the analog loading layer 13. The shielding case 40 may be made of a conductive material, such as metal. The shielding case 40 shields the analog component 14 from outside noise signals. Since the shielding case 40 is mounted on the digital loading layer 23, noise signals at the shielding case 40 would not interfere with the analog area 10. To improve the noise shielding effect of the shielding case 40, the shielding case 40 may be electrically connected to the main ground layer 30 directly.

Since the analog wiring layer 12 is separate from the digital wiring layer 22, noises from the digital area 20 will not interfere with the analog area 10 and disturb the analog components 14 mounted on the analog area 10. In addition, the analog ground layer 11 of the analog area 10 is connected to the digital ground layer 21 of the digital area 20 to form the main ground layer 30. Thus, noise signals produced by the analog area and the digital area 20 are absorbed quickly. In addition, since the analog ground layer 11 of the analog area 10 is connected to the digital ground layer 21 of the digital area 20, the analog wiring layer 12 may be electrically connected to the digital wiring layer 22 via the analog ground layer 11 and the digital ground layer 21, so that a line trace of the circuit board 1 is easier to lay out.

While certain embodiments have been described and exemplified above, various other embodiments will be apparent to those skilled in the art from the foregoing disclosure. The present disclosure is not limited to the particular embodiments described and exemplified, and the embodiments are capable of considerable variation and modification without departure from the scope of the appended claims.

What is claimed is:

1. A circuit board, comprising:
an analog area comprising an analog ground layer and an analog wiring layer formed on the analog ground layer; and
a digital area comprising a digital ground layer connected with the analog ground layer to form a main ground layer, and a digital wiring layer formed on the digital ground layer, wherein the digital wiring layer is separated from the analog wiring layer.

2. The circuit board as claimed in claim 1, wherein the analog wiring layer and the digital wiring layer are formed at a same side of the main ground layer.

3. The circuit board as claimed in claim 1, wherein the analog wiring layer is substantially coplanar with the digital ground layer and the analog ground layer is substantially coplanar with the digital wiring layer.

4. The circuit board as claimed in claim 1, wherein the analog area further comprises an analog loading layer formed on a surface of the analog wiring layer away from the analog ground layer; the digital area further comprises a digital loading layer formed on a surface of the digital wiring layer away from the digital ground layer.

5. The circuit board as claimed in claim 4, wherein the analog loading layer is substantially coplanar with the digital loading layer.

6. The circuit board as claimed in claim 4, further comprising an analog component mounted on the analog loading layer, and a shielding case mounted on the analog or digital loading layer receiving the analog component therein.

7. The circuit board as claimed in claim 6, wherein the analog loading layer is separate from the digital loading layer; the shielding case is mounted on the digital loading layer surrounding the analog loading layer.

8. The circuit board as claimed in claim 6, wherein the shielding case is electrically connected to the main ground layer.

9. The circuit board as claimed in claim 6, wherein the shielding case is made of a conductive material.

10. The circuit board as claimed in claim 9, wherein the shielding case is made of a metal.

11. The circuit board as claimed in claim 6, wherein the analog component is a component selected from the group consisting of an audio chip, an amplifier, a power supplier, and a microphone.

12. A circuit board, comprising:
an analog area with an analog component mounted thereon, the analog area comprising an analog ground layer and an analog wiring layer formed on the analog ground layer; and
a digital area with a digital component mounted thereon, the digital area comprising a digital ground layer connected with the analog ground layer to form a main ground layer and a digital wiring layer formed on the digital ground layer, wherein the digital wiring layer is separated from the analog wiring layer.

13. The circuit board as claimed in claim 12, wherein the analog wiring layer and the digital wiring layer are formed at a same side of the main ground layer.

14. The circuit board as claimed in claim 12, wherein the analog wiring layer is substantially coplanar with the digital ground layer and the analog ground layer is substantially coplanar with the digital wiring layer.

15. The circuit board as claimed in claim 12, wherein the analog area further comprises an analog loading layer formed on a surface of the analog wiring layer away from the analog ground layer; the digital area further comprises a digital loading layer formed on a surface of the digital wiring layer away from the digital ground layer.

16. The circuit board as claimed in claim 15, wherein the analog loading layer is substantially coplanar with the digital loading layer.

17. The circuit board as claimed in claim 15, further comprising a shielding case mounted on the analog or digital loading layer receiving the at least one analog component therein.

18. The circuit board as claimed in claim 17, wherein the analog loading layer is separate from the digital loading layer; the shielding case is mounted on the digital loading layer surrounding the analog loading layer.

19. The circuit board as claimed in claim 17, wherein the shielding case is electrically connected to the main ground layer.

20. The circuit board as claimed in claim 17, wherein the shielding case is made of a conductive material.
